(19) United States
(12) Patent Application Publication
(10) Pub. No.: US 2025/0035717 A1
(43) Pub. Date: Jan. 30, 2025

(54) METHOD AND SYSTEM FOR PRODUCING AN xMR MAGNETIC FIELD SENSOR

(71) Applicant: 3D-MICROMAC AG, Chemnitz (DE)

(72) Inventors: Alexander Böhm, Marienberg (DE); Bernd Keiper, Burgstädt (DE); Christian Belgardt, Chemnitz (DE); Michael Grimm, Chemnitz (DE); Michael Werner, Chemnitz (DE); Sven Albert, Penig (DE); Uwe Kober, Chemnitz (DE)

(73) Assignee: 3D-MICROMAC AG, Chemnitz (DE)

(21) Appl. No.: 18/709,462

(22) PCT Filed: Nov. 7, 2022
(86) PCT No.: PCT/EP2022/081008

§ 371 Date: May 10, 2024

(30) Foreign Application Priority Data
Nov. 10, 2021 (DE) 10 2021 212 669.3

(51) Int. Cl. G01R 33/00; B23K 26/50; G01R 33/09

(52) U.S. Cl. CPC G01R 33/0052; B23K 26/50; G01R 33/09

(57) ABSTRACT

A method for fabricating an xMR magnetic field sensor with at least one xMR sensor element from a workpiece containing an xMR multilayer system, including a magnetically hard reference layer with a reference magnetization direction. The method involves a programming operation to set or modify the reference magnetization direction in a sensor region by locally heating the reference layer beyond a threshold temperature using laser radiation, exposing the heated region to an external magnetic field to set the reference magnetization direction, and subsequently cooling the region. The laser processing operation employs a mask projection technique, where a mask with at least one aperture is irradiated with laser pulses, and the fully illuminated aperture region is imaged onto the processing plane using an imaging lens.

### CROSS-REFERENCE TO RELATED APPLICATIONS

This application is a US national stage filing under 35 U.S.C. § 371 of International Application No. PCT/EP2022/081008, filed Nov. 7, 2022, which claims priority to German Patent Application No. 10 2021 212 669.3, filed Nov. 10, 2021, each of which is incorporated herein by reference in its entirety.

### TECHNICAL FIELD

This disclosure relates to a method and a system for producing an xMR magnetic field sensor.

### BACKGROUND

Detecting magnetic fields with the aid of magnetic field sensors is a type of sensor technology that can be used in numerous industrial applications, for example, when angle-detecting the exact position of a steering wheel in a car, when capturing and monitoring the rotation in a brushless DC motor, when measuring the position and interaction of objects for Internet-of-Things (IoT) applications, when contactlessly measuring electric currents and position capturing by an e-Compass for many different mobile devices, including systems of virtual reality (VR).

Many magnetic field sensors utilize magnetoresistive effects, that is to say effects that describe the change in the electrical resistance of a material due to an external magnetic field being applied. This includes in particular the anisotropic magnetoresistive effect (AMR effect), giant magnetoresistance (also referred to as GMR effect), tunnel magnetoresistance (TMR) or TMR effect, and the planar Hall effect.

Highly sensitive magnetic field sensors can be constructed by using GMR or TMR sensor elements. The abbreviations GMR and TMR will be combined herein in the abbreviation “xMR”. An xMR sensor element utilizes the GMR effect or the TMR effect. These are observed in structures that consist of thin alternating magnetic and non-magnetic layers. The effect consists in the electrical resistance of the layer structure being dependent on the mutual orientation of the magnetizations of the magnetic layers.

Generally, an xMR sensor element has an xMR multilayer system comprising a magnetically soft (ferromagnetic) detection layer having a magnetization direction that is relatively easy to vary using an external magnetic field, a (by comparison) magnetically hard reference layer having a specifiable reference magnetization direction, and a non-magnetic intermediate layer arranged between the detection layer and the reference layer. In GMR sensor elements, the intermediate layer is electrically conductive, and in TMR sensor elements, the intermediate layer is a very thin insulator layer.

The electrical resistance of an xMR sensor element is lower when the two magnetization directions of the layers are parallel to each other, and is higher when they are not parallel. If the direction of the magnetization of one of the layers (reference layer) is fixed, the change in the electrical resistance follows the direction of the magnetization of the other layer. This causes a sensor functionality due to what is known as the spin valve effect or tunnel valve effect. By measuring the electrical resistance or the tunnel current, it is thus possible to infer the orientation of the external magnetic field relative to the orientation of the magnetic field of the reference layer.

Producing an xMR sensor element comprises setting the magnetic alignment of the reference magnetic layer in the desired sensitivity direction. The selected magnetization direction defines the sensitivity axis.

In methods of the type considered herein, a programming operation is provided herefor, with which the spatial orientation of the reference magnetization direction is set in accordance with a specification. To this end, the reference layer is heated in a sensor region in a locally delimited manner to above a threshold temperature by laser radiation, the heated sensor region of the reference layer is exposed to an external magnetic field with a specifiable field direction to set the reference magnetization direction, and the sensor region is subsequently cooled again to below the threshold temperature. The threshold temperature is also referred to as “blocking temperature”. This way of defining the magnetization direction is also referred to as “pinning”.

If a plurality of xMR sensor elements, for example, with a Wheatstone bridge sensor circuit are electrically connected, xMR magnetic field sensors having a high sensitivity and stable output signals can be produced. As part of the miniaturization of sensor systems, such sensors can nowadays be manufactured in a monolithic design including read electronics. To set up a Wheatstone bridge sensor circuit, xMR sensor elements having locally differing directions of magnetization of the reference layers are required.

Examples relating to the construction and production of xMR magnetic field sensors are disclosed, for example, in WO 02/082111 A1 or in US 2019/0227129 A1.

It could therefore be helpful to provide a method and a system for producing xMR magnetic field sensors that permit economical manufacturing of such components with high quality.

### SUMMARY

We provide a method for producing an xMR magnetic field sensor with at least one xMR sensor element from a workpiece having one or more layers of an xMR multilayer system, including at least one magnetically hard reference layer with a reference magnetization direction, the method including: a programming operation in which a spatial orientation of the reference magnetization direction in a sensor region provided to form an xMR sensor element is set and/or modified by heating the reference layer in a laser processing operation in the sensor region in a locally delimited manner beyond a threshold temperature by laser radiation, the heated region of the reference layer is exposed to an external magnetic field with a specifiable field direction to set the reference magnetization direction, and the heated region is subsequently cooled again to below the threshold temperature, wherein the laser processing operation includes a mask projection operation, in which a mask with at least one mask aperture is arranged in a mask plane arranged at a distance from a processing plane of the laser processing operation; a region of the mask containing the mask aperture is irradiated with one or more laser pulses; and a region of the mask aperture that is fully illuminated with laser radiation is imaged into the processing plane with the aid of an imaging lens arranged between the mask plane and the processing plane.

We also provide a system that produces xMR magnetic field sensors, wherein an xMR magnetic field sensor has an xMR sensor element having an xMR multilayer system that has at least one magnetically hard reference magnetic layer with a specifiable reference magnetization direction, including a control unit; a laser processing station having a laser processing unit, controllable by the control unit, for producing a laser beam that is directable at a laser irradiation region in a processing plane of the laser processing unit; a workpiece holding apparatus that receives a workpiece to be processed at a defined location; a workpiece movement system that moves the workpiece to be processed in a working region of the laser processing station as a reaction to movement signals from the control unit; a settable magnetization device that produces a magnetic field with a variably specifiable field direction which at least partially penetrates the workpiece in the laser irradiation region when the magnetization device is in a working configuration; a mask projection system having a mask holding unit that arranges a mask forming at least one mask aperture in a mask plane located at a distance upstream of the processing plane and having an imaging lens to image the mask plane into the processing plane of the laser processing unit.

### BRIEF DESCRIPTION OF THE DRAWINGS

FIGS. 1A-1D show an oblique view illustrating the sensor principle in FIG. 1A, a section through the layer construction of an xMR sensor element before programming in FIG. 1B, the same layer construction after programming in FIG. 1C, and a plan view of an example of an xMR sensor arrangement with a plurality of sensor elements in FIG. 1D.

FIG. 2 schematically shows components of a laser processing station of a system for producing xMR magnetic field sensors.

FIG. 3 schematically shows a plan view of an interchange mask according to an exemplary embodiment.

FIG. 4 shows a plan view of the processing plane including magnetization direction and cooling.

FIG. 5 shows a schematic side view of a flexible magnetization device arranged between the imaging lens and the processing plane.

FIG. 6 schematically shows a side view from the region of a different magnetization device in combination with a cooling device and a heating device and a device for the controlled change of two magnet units.

FIGS. 7A, 7B show diagrams for elucidating method variants with a selective setting of the temporal pulse shapes for optimizing heating in one exemplary embodiment.

### DETAILED DESCRIPTION

Our methods and systems produce xMR magnetic field sensors. An xMR magnetic field sensor has at least one xMR sensor element. An xMR sensor element uses the GMR effect or the TMR effect to detect magnetic fields. xMR sensor elements are produced from one workpiece having one or more layers of an xMR multilayer system. The workpiece comprises at least one magnetically hard reference layer with a reference magnetization direction. The reference layer can be a reference layer system having a plurality of reference layers. Other layers of an xMR multilayer system can likewise already be present on the workpiece or can be applied later, if appropriate, for example, because they are not supposed to be heated.

In addition to the magnetically hard reference layer of the xMR sensor element, the workpiece in many embodiments already comprises, before processing begins, a magnetically soft or ferromagnetic detection layer that has a magnetization direction that is variable by way of an external magnetic field and a non-magnetic intermediate layer arranged between the detection layer and the reference layer. Further layers can be provided in addition to these layers.

A method step in generic methods is what is known as a programming operation, which is designed to set and/or change the spatial orientation of the reference magnetization direction in a sensor region. The term “sensor region” denotes a spatially delimited region of the workpiece in which an xMR sensor element is to be produced. To accomplish this, the reference layer is heated in a laser processing operation in the sensor region in a locally delimited manner to above a threshold temperature by laser radiation. The heated region of the reference layer is exposed to an external magnetic field with a specifiable field direction to set the reference magnetization direction, and the heated region is subsequently cooled again to below the threshold temperature. During cooling in the external magnetic field, the ideally magnetically saturated reference layer is fixed in the programmed direction, which is also referred to as “pinning”.

When the reference layer is heated to above this threshold temperature, what is known as the “exchange bias effect” disappears, and the direction of magnetization is consequently lost. The external magnetic field should be strong enough to saturate the reference layer in the chosen new direction. During cooling in the external field, the saturated reference layer is fixed in the programmed direction. This definition of the magnetization direction is also referred to as “pinning”.

The partial process that permits locally delimited heating of a sensor region by laser radiation in the laser incidence region under very precisely specifiable conditions is also referred to as “selective laser annealing”.

In one example, provision is made for the laser processing operation to comprise a mask projection operation. To this end, a mask with at least one mask aperture or mask orifice is arranged in a mask plane that is arranged at a distance from a processing plane of the laser processing operation. The processing plane is the plane in which the laser radiation is incident on the workpiece and is intended to interact therewith. The distance relates to the optical distance along the beam path of the laser radiation. The beam path may be rectilinear, but it may also be folded by at least one deflection direction.

For laser processing, pulsed laser radiation is used, so that a region of the mask containing the mask aperture is irradiated with one or more laser pulses of the pulsed laser radiation.

A region of the mask aperture that is fully illuminated with laser radiation is imaged into the processing plane with the aid of an imaging lens arranged in the beam path between the mask plane and the processing plane. The laser radiation is incident on the workpiece in this laser incidence region (also referred to as laser spot).

The mask projection operation can enable the shape, the location and the size of the laser spot, and consequently also of the sensor region to be heated, to be specified with a high degree of precision with relatively sharp boundaries owing to the design of the mask or the mask aperture and the imaging properties of the imaging lens. When the surface element (sensor region) provided to form the sensor element is irradiated by way of mask projection, it is possible in many cases to irradiate a complete or entire sensor region with one laser pulse and to thus program it.

A system suitable for carrying out the method accordingly has a mask projection system with a mask holding unit for arranging a mask in a mask plane disposed at a distance upstream of the processing plane, and an imaging lens for imaging the mask plane into the processing plane of the laser processing unit. The mask has at least one mask aperture or mask orifice for letting through a portion of the laser beam that is to be transmitted. In this way, the spatial beam shape on the laser incidence region of the workpiece can be specified with sharp delimitation.

By using the mask projection, the spatial extent of the laser spot on the workpiece can be adapted to the shape of the sensor element to be programmed. For example, rectangular mask apertures with sides of different lengths or square mask apertures can be used. Depending on the available laser energy or depending on the required maximum size of the surface on the workpiece that is to be irradiated with sufficient laser fluence, it is sometimes possible to irradiate an entire sensor element with a single laser pulse or even to irradiate a complete sensor with a plurality of sensor elements that are intended to be programmed with the same spatial orientation of the magnetization with one laser pulse. In this case, the mask would have a plurality of mask apertures that correspond to the sensor elements to be programmed. If the available laser energy or surface area is not sufficient for this purpose, it is also possible to irradiate only a portion of a sensor element with one laser pulse and to realize the programming of a complete sensor element with a plurality of laser pulses.

In addition to the advantages that come about with the exact specification and good illumination of the respective sensor regions, mask projection also offers advantages in terms of magnetization. This is because, in some embodiments, provision is made for components of the magnetization device to be arranged between the imaging lens and the processing plane. These components, for example, one or more permanent magnets and the associated holder, can thus be positioned near the workpiece, and so the magnetization can be effected with high efficiency and precise specification of the field strength and field direction. The external magnetic field can thus be coupled in from an intermediate region between the imaging lens and the processing plane.

A refinement of the method and of the system is characterized by homogenization of the laser radiation in a manner such that an intensity distribution of the laser radiation that passes through a mask aperture and is incident on a sensor region is substantially constant over the entire cross section. The term “substantially constant” means that the local intensity in the irradiated region varies by no more than 20%, in particular by no more than 10%. In this way, sufficiently uniform properties can be produced over the entire cross-sectional area of a sensor element. The homogenization can also cause the threshold temperature or blocking temperature in the entire irradiated region of the sensor element to be exceeded substantially simultaneously, without the laser damage threshold of the material being exceeded.

Preferably, the homogenization of the laser radiation is produced in a region between the laser radiation source and the mask plane in a manner such that the intensity distribution of the laser radiation incident on the mask aperture can be specified by the homogenization. To this end, an optical homogenization system for homogenizing the intensity distribution within the laser beam can be provided between the laser radiation source and the mask plane. The homogenization system can have, for example, at least one diffractive optical element (DOE), at least one spatial light modulator (SLM) and/or at least one beam-shaping optical fiber.

As an alternative, it would be possible to broaden the laser beam generated by the laser radiation source to a significantly greater diameter before it is incident on the mask and to position it such that only a comparatively homogeneous region near the center of the Gaussian profile of the intensity distribution in the broadened laser beam can pass through the mask orifice. However, the deviations from a homogeneous beam profile are in this case usually significantly greater than when using a dedicated homogenization system between the laser radiation source and the mask.

In some embodiments, special measures are taken for an expedient temperature management.

One measure that has proven to be particularly useful consists in setting a temporal pulse shape of the laser pulses. For this purpose, a pulse property setting device for variably setting pulse properties of the laser pulses can be provided on the system, wherein the device is configured in one mode for setting the temporal pulse shape of the laser pulses. That means that a desired temperature profile of the heating can be influenced by specifying the profile of the laser intensity over time within a pulse. By adapting the temporal pulse shape, a more exact setting of the maximum temperature in the irradiated region of the sensor element becomes possible, among other things. There exist laser systems that enable such adaptation of the temporal pulse shape via a corresponding input signal. In this case, the temporal pulse shape is preferably set such that the blocking temperature or threshold temperature is quickly and reliably reached, but is exceeded comparatively only by a small extent in the entire region to be programmed. However, the laser damage threshold of the irradiated workpiece material must not be exceeded in the process. The temporal pulse shape of the laser pulses can for this purpose be set, for example, such that a maximum intensity within a laser pulse is reduced in comparison with a regular laser pulse (which is not temporally controlled, for example, temporally approximately Gaussian) and a decay gradient of the laser intensity after the maximum intensity is exceeded is lower than for a regular laser pulse.

With suitable adaptation of the temporal pulse shape to the temperature-dependent change in absorption of the irradiated material, more uniform heating of the sensor region can be achieved by decreasing the energy introduction as the temperature rises (and the increase in absorption correspondingly rises).

A further contribution to the temperature management in some refinements consists in a heating device that is controllable via the control unit being provided to actively heat a workpiece held by the workpiece holding apparatus to an operating temperature that is clearly higher than the ambient temperature but reliably lies under the threshold temperature. By heating the workpiece before laser processing and, if appropriate, by stabilizing the temperature, the change in temperature of the workpiece in the sensor region during processing (and thus the change in optimum laser parameters) can be avoided or reduced. Increasing the starting temperature of the workpiece can additionally result in the required laser energy being reduced. Among other reasons, this is due to the fact that, depending on the material, as the temperature increases, the absorption coefficient of the workpiece material also increases, and therefore the energy requirement may additionally drop and the process stability increases. It should also be taken into account that the workpieces frequently already have semiconductor components, which are required, for example, for the function of the sensors. To reliably ensure that these semiconductor components are not damaged, it is expedient to limit the temperature increase to noncritical values. The operating temperatures set by heating are preferably 30° C. to 250° C., in particular 50°° C. to 100° C.

In many method variants, no active cooling is necessary because the temperature difference between the sample temperature and the threshold temperature is relatively large and only a small volume of the sample is heated, and so a high cooling rate is achieved simply by way of thermal conduction in the workpiece. In other cases, however, active cooling may be sensible. Provision is therefore made according to one refinement for the workpiece to be actively cooled to a temperature below the threshold temperature during and/or after irradiation with the laser. In addition, a cooling fluid can be applied in a locally delimited region, for example. For example, cold gas (e.g. air or nitrogen) or a liquid mist (for example, water spray) can be used for cooling.

Depending on the method variant and on the layer system used, irradiation with the laser can also be advantageous in an inert gas atmosphere.

A significant increase in the throughput of finished sensor elements compared to known methods is achieved according to one refinement by the workpiece being moved at a constant speed in a movement direction during the irradiation with the laser, so that pulse triggering takes place during the movement of the workpiece without stopping. Mass production high-speed processes can be realized by this “on-the-fly” pulse triggering, or OTF pulse triggering, during the movement. A preferred system accordingly has a movement system that is suitable for moving the workpiece at a constant speed in a movement direction during the irradiation with the laser and triggering pulses during the movement of the workpiece. In such refinements, the workpiece can thus be moved continuously at a relatively high speed during the processing to enable an efficient mass production process. Feed rates can be, for example, 50 mm/s to 500 mm/s, in particular 150 mm/s to 300 mm/s, or, if appropriate, above or below these values.

However, depending on the chosen feed rate of the workpiece and the chosen pulse duration, disturbing motion blur may occur during the irradiation with the laser, which manifests in the irradiated region being longer in the movement direction than it should be according to the desired dimensions of the sensor region in the movement direction. To counteract this, a system according to one refinement has a motion-blur compensation device with at least one controllable component that is controlled such that, during the duration of a laser pulse, a laser beam incidence region on the workpiece is guided along to compensate any smearing of the incidence region in the movement direction of the workpiece. The motion blur can be at least partially compensated by an additional movement during the laser pulse duration.

In some embodiments, the motion-blur compensation device has for this purpose a dynamically controllable laser beam deflection device arranged in a laser beam path between the laser source and the processing plane. This deflection device, for example, a deflection mirror, can be dynamically pivoted, for example, by a piezo actuator to produce the compensatory movement. The deflection mirror can also be replaced by a scanner. The deflection device can be controlled during the laser pulse in a manner such that the laser spot, that is to say the image of the mask, follows the movement of the workpiece. Between the laser pulses, the mirror is then moved back to the starting position.

Alternatively, provision may be made for the motion-blur compensation device to be configured to displace the mask holding unit during the duration of a laser pulse and to shift it back between laser pulses. For this purpose, a movement axis of the mask holding unit can be correspondingly controlled. This, too, can cause the laser spot or the image of the mask to follow the movement of the sample.

It is also possible that the controllable deflection mirror or scanner, or the X-Z-axes of the mask, are controlled after the irradiation of a surface element such that the laser beam jumps to a surface element in an adjacent line with sensor regions and a further laser pulse is triggered and subsequently jumps back to the position of the current line. In this way, two or more lines can be processed in one passage, thus additionally increasing the processing speed.

Alternatively or in addition, other measures may be provided to shorten the processing times for producing sensors or to increase the efficiency of the process. In some embodiments, parallelization of the irradiation of the mask plane is provided for this purpose, in which, in addition to a first laser beam for irradiating a first region in the mask plane, at least one second laser beam for simultaneously irradiating a second region in the mask plane is produced, wherein the irradiated regions in the mask plane have a lateral offset with respect to one another. In this way, two or more sensor regions which are laterally offset with respect to one another can be simultaneously irradiated and thereby set and/or modified. The corresponding laser processing unit can thus be configured for parallel processing. There are different possibilities for implementing this. In one variant, a multispot beam shaping element is arranged in the beam path of a laser beam, which multispot beam shaping element is configured to produce from an individual incident laser beam a first laser beam and at least one second laser beam with different propagation directions. The beam shaping element can be, for example, a diffractive optical element (DOE), possibly in the form of a computer-generated hologram (CGH). The separate partial beams (first and second laser beam) can then be incident on different regions of the mask, and the respective mask apertures that are illuminated thereby are then imaged together or simultaneously via the imaging lens. By making the multispot beam shaping element interchangeable, it is possible to easily achieve an adaptation to different distances.

Alternatively or in addition, it is also possible to use more than one laser radiation source at the same time. Such a laser processing unit preferably comprises a first laser radiation source for producing a first laser beam and at least one second laser radiation source for producing a second laser beam, wherein the two laser beams are directed at laterally offset regions of the mask, and illuminated mask apertures in the offset regions are imageable or are imaged together into the processing plane by the imaging lens. A plurality of laser sources, for example, two, three or four or more, which act on the sample via the same optical unit and the same mask can thus be used. In this case, different regions of the mask are used. The positions of the two laser beams can be flexibly settable so that different distances of the sensor elements are easy to realize.

The system should be able to reliably manufacture different sensor types, specifically including those that contain regions with different spatial orientations of magnetization within a sensor. According to one refinement, a contribution to this is made by the magnetization device having two or more different magnet units. Different magnet units can include different numbers and/or arrangements of permanent magnets and possibly pole shoes and/or other magnetic-field-generating or magnetic-field-guiding parts and be constructed such that different spatial orientations of magnetization and different magnetic field strengths within a sensor element to be programmed can be realized.

In one refinement, provision is made for the magnetization device to have two or more magnet units (for example, with permanent magnets), which can be held in a movably mounted magnet holder and can, by displacing the magnetic holder, be arranged selectively in a working position in which they provide the external magnetic field for programming. The magnet units, which are preferably constructed with permanent magnets, can provide the magnetic field in different orientations of its magnetic axes and/or with different magnetic field strengths. Consequently, a plurality of magnet units can be arranged at or on an electrically controllable revolver or a linear construction so that the magnet units can be interchanged with electrical control.

A magnet unit can be mounted rotatably about an axis of rotation so that the spatial orientation of magnetization in a plane parallel to the processing plane can ideally be continuously set at an angle of 0° to 360°.

It is also possible that 3D sensors are intended to be produced. It may then additionally be necessary to realize specific spatial orientations of magnetization with respect to the Z-axis (perpendicular to the processing plane). This is also possible with the aid of suitable magnet units.

Further advantages will become apparent from the description of exemplary embodiments explained below on the basis of the figures.

The following text describes exemplary embodiments of methods and systems for producing xMR magnetic field sensors which utilize specific variants of “selective laser annealing” during the partial process of “programming” to achieve locally delimited heating of a sensor region by laser radiation under very precisely specifiable conditions. xMR magnetic field sensors are highly sensitive magnetoresistive magnetic field sensors that utilize the GMR effect or the TMR effect. The abbreviations GMR and TMR will be combined herein in the abbreviation “xMR”.

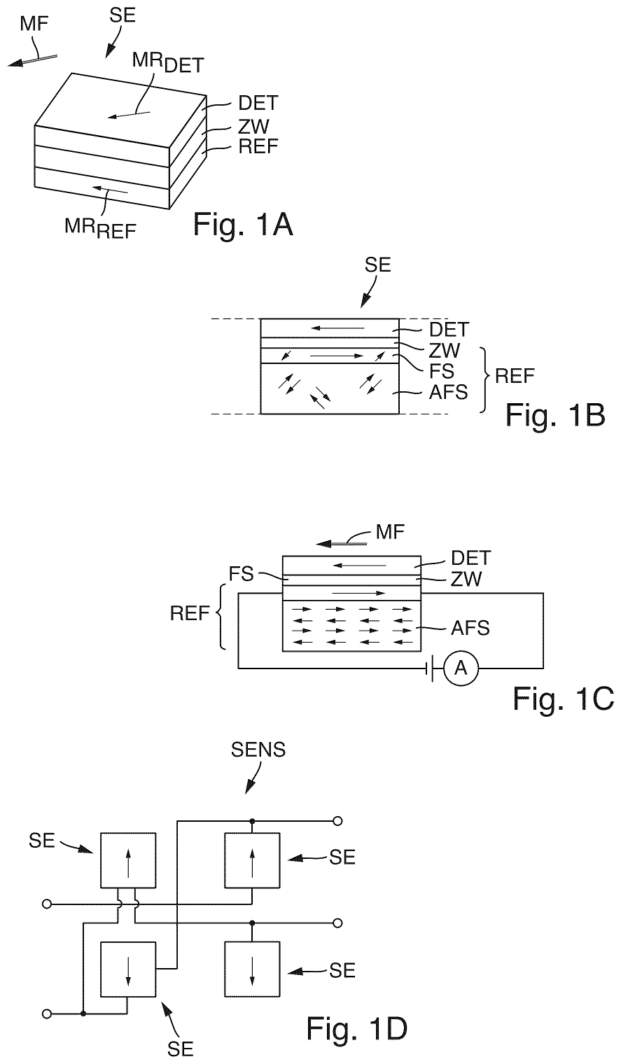

FIG. 1A schematically shows a section through the layer construction of an xMR sensor element SE, which has alternating thin magnetic and non-magnetic layers. The electrical resistance of the layer structure depends on the mutual orientation of the magnetizations of the magnetic layers symbolized by arrows. The layer structure has a magnetically soft (ferromagnetic) detection layer DET, a (by comparison) magnetically hard reference layer REF, and a non-magnetic intermediate layer ZW arranged between the detection layer DET and the reference layer REF.

The spatial orientation of the magnetization direction MR_{DET} of the detection layer DET can follow the external magnetic field MF. By contrast, the spatial orientation of the magnetization MR_{REF} in the reference layer does not change or hardly changes even under the influence of strong external magnetic fields.

As illustrated in FIG. 1B, the reference layer REF in the example comprises a relatively magnetically soft ferromagnetic layer FS and an antiferromagnetic layer AFS. The spatial orientation of the magnetization direction of the magnetically soft ferromagnetic layer FS is fixed or stabilized by the antiferromagnetic layer AFS via what is known as the “exchange bias effect”.

In the antiferromagnetic layer AFS, the spatial orientation of the magnetization below a threshold temperature T_{B}, or what is known as blocking temperature T_{B}, is not influenceable by an external magnetic field MF. Macroscopically, the antiferromagnetic layer has no magnetization because the magnetic moments of the adjacent magnetic domains that are aligned antiparallel compensate one another (see FIG. 1B). Adjacent magnetic domains also remain antiparallel after programming, but are then all aligned parallel or antiparallel to the external magnetic field (see FIG. 1C). However, once it has been programmed, a spatial orientation of the magnetization in the ferromagnetic layer FS is stabilized by the orientation in the antiferromagnetic layer AFS, with the result that the programmed orientation is not changed or substantially not changed even under strong external magnetic fields.

The thin intermediate layer ZW in GMR sensor elements is non-magnetic and electrically conductive, but in TMR sensor elements it is non-magnetic and non-conductive, that is to say insulating. The electrical conductivity of the intermediate layer (in the case of GMR), measured longitudinally with respect to the layer (see FIG. 1C), or the tunnel current through the intermediate layer (in the case of TMR, measured perpendicularly to the layer) is determined by the spatial orientation of the magnetization of the detection layer in relation to the spatial orientation of the magnetization of the reference layer.

Consequently, the value of the conductivity or of the tunnel current depends on the spatial orientation of the external magnetic field MF, and with a suitable design of the sensor system, the orientation of the external magnetic field can be inferred by evaluating the sensor signals.

The reference layer REF can be programmed (pinned) locally in an external magnetic field beyond the blocking temperature by irradiation with the laser and the resulting heating. Producing an xMR sensor element comprises setting the magnetic alignment of the reference magnetic layer in a desired sensitivity direction. The selected magnetization alignment defines the sensitivity axis of a sensor element.

Frequently, a plurality of xMR sensor elements with different directions of magnetization of the reference layers or differently oriented sensitivity axes are required for the construction of sensor circuits SENS. FIG. 1C shows, by way of example, a Wheatstone bridge sensor circuit, which is recreated on the basis of FIG. 4 of WO 02/082111 A1. Therein, a plurality of (in the present case four) xMR sensor elements SE with different sensitivity axes (arrows) are interconnected. Nowadays, such sensor arrangements can be manufactured in a monolithic design including read electronics from the same workpiece.

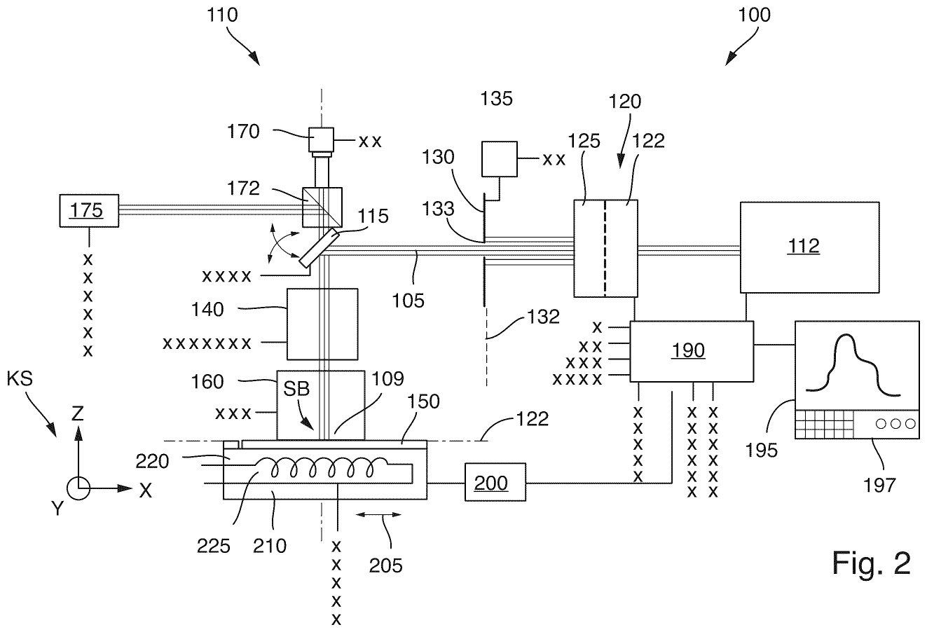

FIG. 2 schematically shows components of a laser processing station 100, which is a functional integral part of an exemplary embodiment of a system for producing xMR magnetic field sensors. The system is configured to carry out methods for programming the spatial orientation of the magnetization of thin layers. This is accomplished in an automated manner by laser-assisted heating of the layer element or sensor element to be programmed to a temperature above the blocking temperature and subsequent cooling to room temperature in the presence of an external magnetic field with the spatial orientation of magnetization that is specified for the layer element to be programmed. The programming can be achieved at a high speed in a mass production high-speed process by on-the-fly (OTF) pulse triggering during the movement without stopping the workpiece 150.

The laser processing station 100 has a laser processing unit 110, which operates with laser radiation from a laser radiation source 112. The latter emits a laser beam 105, which initially propagates in the horizontal direction parallel to the x-axis of the system coordinate system KS. In addition, loading and unloading systems and further peripheral devices are provided at the laser processing station.

The laser-assisted programming of the spatial orientation of the magnetization of the reference layer in magnet sensors is based on the defined heating of the reference layer. All laser wavelengths that are absorbed to a sufficient extent by the layers to be irradiated are suitable herefor. For most layers used this is the case in a large wavelength range, meaning that mostly cost-effective lasers in the near infrared (NIR) wavelength range are used. In the example, a fiber laser with a wavelength of 1064 nm is used. The typically used wavelength range is 500 nm to 3 μm. For irradiating metal layers which are highly reflective in the infrared wavelength range and thus only slightly absorb these wavelengths, the use of green wavelengths (for example, 532 nm) is better suited. Alternatively, it is likewise possible to use the radiation from laser diodes to heat the reference layer. In this case, wavelengths of 600 to 900 nm and 1.3 . . . 1.6 μm are preferably used.

The laser radiation source 112 emits pulsed laser radiation, that is to say individual laser pulses. Laser pulses having pulse durations of 1 ns to 1 ms are preferably used. In one exemplary embodiment, a fiber laser having a wavelength of 1064 nm and a maximum pulse energy of preferably 400 μJ to 5 mJ is used. Adopting the pulse energy of the laser to the process is effected using an electrically controllable attenuator. The laser operates internally at a constant laser pulse repetition rate (preferably 1 to 100 kHz), so that a constant pulse energy/fluence is emitted by the laser. In this case, only the laser pulses required for programming are directed at the workpiece, that is to say laser pulses are directed at the workpiece specifically when a sensor element to be programmed is located in the processing region. Laser pulses that are not required can be directed, for example, at a beam dump absorbing the laser radiation.

The emitted primary laser beam passes through a beam shaping unit 120, which comprises optical components of a beam expansion system 122 and optical components of a homogenization system 125. The homogenization system can contain at least one diffractive optical element (DOE), for example.

Among other effects, the homogenization can have the effect that the blocking temperature or threshold temperature is exceeded substantially simultaneously in the entire irradiated region, without the laser damage threshold of the material being exceeded. The intensity over the cross-sectional area of the laser beam in the mask plane is regularly substantially constant, meaning that only a relatively small deviation of, for example, at most 20%, preferably at most 10%, occurs.

After passing through the beam shaping unit 120, or downstream thereof in the beam path, the expanded laser beam has, over its entire cross section, a relatively uniform or homogeneous intensity distribution, in which local intensity differences are preferably less than 20%, preferably less than 10%, of the maximum local intensity.

The laser processing station 100 is configured for a mask projection method. For this purpose, components of a mask projection system are installed. The system has, among other things, a mask holding unit 135, which can receive an interchangeable mask 130 such that the mask is arranged in a mask plane 132 that is oriented perpendicularly to the beam direction of the laser beam 105. Under the control of a control unit 190 of the laser processing unit, the mask can be linearly displaced parallel and perpendicular to the mask plane 132 by corresponding machine axes and can be rotated and tilted about the mask plane normal direction.

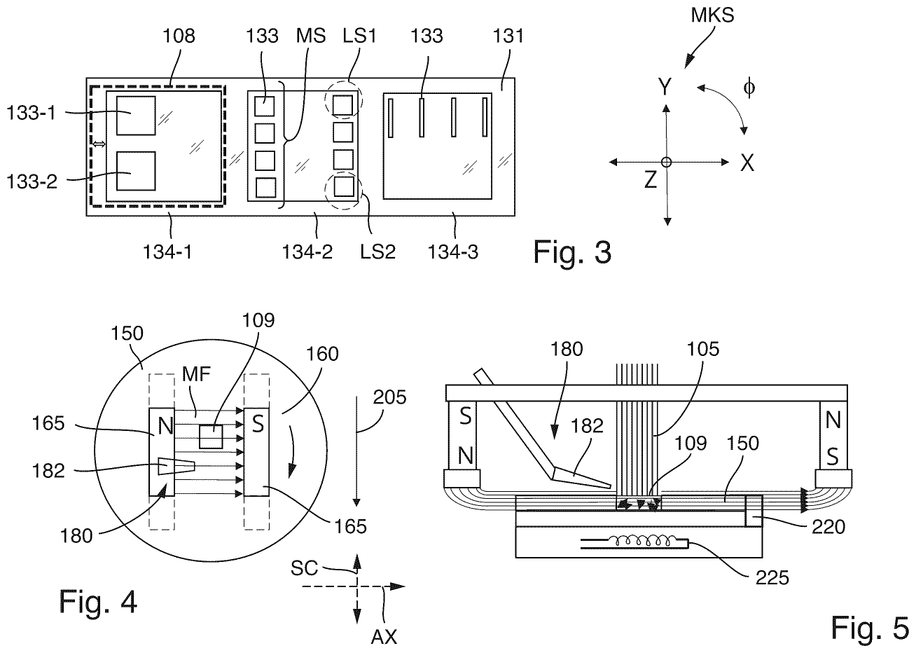

The interchangeable mask has at least one mask aperture, or mask orifice, 133 through which homogenized laser radiation can pass. The mask aperture can have, for example, a rectangular shape with sides of different lengths or a square shape. Details relating to an exemplary interchange mask are shown in FIG. 3.

The mask 130 has an opaque flat mask body 131, on which three different mask regions 134-1, 134-2 and 134-3 are formed. In the first mask region 134-1, there are two square mask orifices 133-1, 133-2 of equal size lying next to each other in the Y-direction of the mask coordinate system MKS. The dashed line denotes the boundary of the rectangular region 108 that is uniformly illuminated by the homogenized laser radiation coming from the beam shaping unit. The size can be approximately 24 mm×24 mm, for example. In this way, two adjacent square sensor regions can be produced on the workpiece at the same time.

In the adjacent second mask region 134-2, there are two mutually parallel rows with in each case four square mask orifices of identical size. These can be illuminated at the same time, and so eight sensor elements of the same magnetization direction can be produced simultaneously. In the adjacent third mask region 134-3, four line-type mask orifices are arranged one next to the other to produce correspondingly shaped sensor elements.

If the available energy or surface area is not sufficient, it is also possible to irradiate only a portion of a sensor element with one laser pulse and to realize the programming of a complete sensor element with a plurality of laser pulses.

The mask holding device 135 allows by way of its actuators different movements of the mask 130. A mask movement with a relatively large travel in the X-direction can be used for the computer-controlled mask change to bring one of the mask regions into the region 108 that is illuminated by the laser beam. Furthermore, short translational movements in the X-, Y- and Z-directions and rotations about the Z-direction (φ-axis) are possible for adjusting the mask position either controlled by a computer or manually. Very flexible process control is thus possible.

The portions or partial beams that have passed through the mask or through the mask orifice(s) are deflected at a beam deflection device 115 and then propagate substantially vertically or parallel to a principal axis 116 of the laser processing unit 110 (parallel to the Z-direction of the machine coordinate system KS) or at more or less acute angles thereto downwards in the direction of a workpiece 150 to be processed.

The beam deflection device 115 has a plane-parallel substrate which consists of synthetic quartz glass and on which a planar surface is formed as a reflective beam deflection surface by it being coated with a dielectric coating that is highly reflective for the laser radiation. In the variant shown, the deflection mirror is tiltable in a highly dynamically controlled manner (see double-headed arrows). This functionality can be used, for example, to avoid motion blur during on-the-fly processing. A periodic change between two adjacent lines of the processing is likewise possible.

The substantially uniformly illuminated mask orifices 133 (one or more) in the mask plane 132 are imaged into the processing plane 122 of the laser processing unit with the aid of an imaging lens 140. The imaging lens 140 is a component of the mask projection system and is arranged optically between the mask plane 132 and the processing plane 122 in a manner such that the mask plane lies in the object plane and the processing plane lies in the image plane of the imaging lens. The optical axis of the imaging lens 120 defines the principal axis 116 of the laser processing unit or corresponds thereto. The imaging can be magnifying, size-reducing or size-maintaining (1:1 imaging). In the example, the imaging lens is a reduction lens with a reduction scale of 15:1.

In the example, the same intensity profile is present in the processing plane 122 as in the mask plane but is reduced in terms of its scale such that the intensity value is increased. The images of the uniformly illuminated mask apertures form uniformly illuminated, for example, rectangular, laser beam incidence regions or laser spots 109 of a precisely specified shape on the workpiece surface.

If processing is effected by mask projection, a relatively large region of the workpiece, for example, in the order of 0.5 mm×0.5 mm to 5 mm×5 mm, can be irradiated in a structured manner with a single laser pulse.

To enable a high-speed process with on-the-fly (OTF) pulse triggering during the movement without stopping the workpiece 150, the laser processing station 100 furthermore has a workpiece movement system 200, which is configured to move, as a reaction to movement signals from the control unit 190, a workpiece to be processed in a horizontal movement direction 205 perpendicular to the principal axis 116 of the laser processing station.

In the configuration of FIG. 2, the workpiece movement system 200 comprises a substrate stage 210, which can be moved parallel to the (horizontal) X-Y-plane of the system coordinate system and be displaced in the height direction (parallel to the Z-direction) very precisely to a desired position and also rotated about a vertical rotation axis (PHI axis). For this purpose, precisely controllable electrical direct drives are provided in the example.

The substrate stage 210 carries a workpiece holding apparatus 220 for receiving a workpiece 150 to be processed at a defined location. The workpiece 150 is a wafer having a layer structure with alternating thin magnetic and non-magnetic layers and possibly further structures for producing xMR sensor elements.

The laser processing station furthermore comprises a magnetization device 160 which is settable with the aid of signals from a control unit 190 to produce a magnetic field with a variably specifiable field direction which at least partially penetrates the workpiece in the laser irradiation region and in the area surrounding it when the magnetization device is in a working configuration. The magnetic-field-producing components of the magnetization device, in particular permanent magnets, are arranged geometrically very close to the workpiece between the imaging lens 140 and the processing plane 122 and can operate very precisely and with a high efficiency due to the small distance from the layers to be magnetized. Exemplary embodiments of magnetization devices are shown in FIGS. 4, 5 and 6.

FIG. 4 schematically shows a plan view of the processing plane or of the top side of the workpiece 150 to be processed. The magnetization device 160 has a magnet unit with two permanent magnets 165, which are held in a movably mounted magnet holder and are arrangeable selectively in a working position by displacing the magnet holder, wherein the permanent magnets are held with different orientations of their magnetic axes (straight connecting line between the north pole N and the south pole S) and/or provide different magnetic field strengths.

With the aid of the magnetization device 160, a homogeneous magnetic field MF, represented by the group of arrows, which forces the alignment of the magnetization of the reference layer in this direction during programming is produced in the processing plane. The field lines extend in the region of the laser spot substantially parallel to the layer extent of the layers or to the workpiece surface. Directly after the heating in the region of the square image of the mask aperture (laser spot 109), cooling takes place with the aid of the cooling fluid applied through the nozzle 182 if the workpiece continuously moves in the direction of the continuous workpiece movement (arrow).

By rotating the magnetization device or the magnet unit about the Z-direction (alternatively, the rotation of the workpiece is also possible), the spatial orientation of the magnetization within a plane (for example, the X-Y-plane) can be set at an angle of 0 to 360°, so that it is possible to set each desired direction of magnetization for 2D sensors (see FIG. 4).

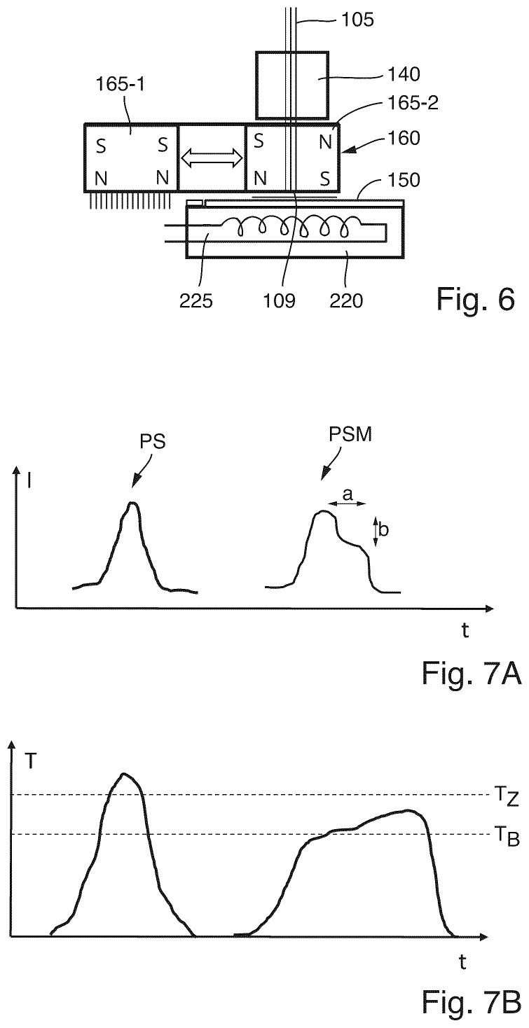

If the intention is to produce 3D sensors, it is additionally necessary to realize the spatial orientation of the magnetization with respect to the Z-axis. For this purpose, provision may be made for a plurality of magnet units of the magnetization device to be arranged on an electrically controllable revolver or linear construction (see FIG. 6) so that the magnet units can be interchanged with electrical control (see double-headed arrow in FIG. 6).

The magnetization device 160 in FIG. 6 has two different magnet units 165-1, 165-2, which each have two permanent magnets. The latter are arranged next to each other in the magnet unit 165-1 with a parallel orientation and in the magnet unit 165-2 with an antiparallel orientation of their polarities. In this case, the magnet unit 165-2 arranged in the working position makes available a spatial orientation of the magnetization parallel to the X-Y-plane, while a spatial orientation of the magnetization perpendicular to the X-Y-plane can be provided with another magnet unit 165-1. It is likewise possible with this system to provide different magnet units with which different magnetic field strengths can be realized. Different magnetic field strengths may be required, for example, for different layer systems or sensor configurations.

The laser processing station 100 is furthermore equipped with controllable devices for temperature management. The workpiece holder 220 is designed as a thermal chuck and comprises a heating device 225 which is, for example, electrically operable and with which a workpiece 150 held by the workpiece holding apparatus 220 can be heated to an operating temperature of significantly above room temperature (20° C.). We found that it is possible hereby to achieve processing results that are frequently of better quality. Among other things, it is possible in some materials for the heating to cause the absorption coefficient of the workpiece material to increase, with the result that less laser energy for heating the sensor element regions is required. In addition, heating beyond the threshold temperature is effected with a relatively small, easily controllable temperature increase.

Furthermore provided is a cooling device 180 with which the heated workpiece material can be actively cooled to below the threshold temperature. Significantly higher cooling rates than in the case of passive cooling are thus achieved. The cooling can be effected continuously or be triggered cyclically only after the irradiation by the laser.

In the example, cold gas or a liquid mist (for example, water spray) is used for cooling, which flows through the illustrated spray nozzle 182 onto the workpiece 150 in the immediate vicinity of the laser incidence region 109. Water cools particularly efficiently by way of withdrawing the relatively large evaporation heat from the heated workpiece surface. The water quantity should be set such that it evaporates completely, if possible. As illustrated, the cooling should be arranged in the movement direction 205 downstream of the laser head and be spatially limited to the region of the heating zone or its immediate surrounding area. If appropriate, a cooling pulse can be activated in the time period immediately after a heating pulse for only a short time as long as the heated region is situated in the cooling zone. The active cooling can likewise prevent adjacent regions which are not irradiated from being heated too much due to thermal conduction.

As mentioned above, the workpiece is moved continuously at a relatively high speed during the processing to enable an efficient mass production process. This movement is produced via the movement system 200. Depending on the chosen feed rate and the chosen pulse duration, motion blur may occur during the irradiation with the laser. At a speed of the workpiece transport, chosen by way of example, of 250 mm/s and a laser pulse duration of 100 μs, this motion blur lies, for example, in the region of 25 μm, so that a region that is greater than planned by 25 μm is irradiated in the movement direction. In addition, the first and last 25 μm of the irradiated structure in the movement direction are not irradiated with the full laser energy. As a result, deviations of the laser processing or the programming that exceed the admissible tolerances may occur.

To counteract this, the system has a motion-blur compensation device. In the example, the deflection mirror 115 is used as part of that compensation device. The deflection mirror 115 is designed to be electrically controllable with the aid of piezo drives or in another way, and can be controlled during a laser pulse in a manner such that the laser spot 109 produced, that is to say the image of the mask on the workpiece, can follow the movement of the workpiece 150. Between two successive laser pulses, the mirror is then moved back to its starting position. In FIG. 2, the compensatory movement taking place in the direction of the sample movement is represented by the small double-headed arrows by the deflection mirror 115.

In FIG. 3, another possible compensatory movement is represented by the double-headed arrow by the first mask region 134-1, which is effected here via a mask movement in the X-direction.

In some embodiment variants, the controllable deflection mirror or a scanner, or the X-Z-axes of the mask, are controlled after the irradiation of a surface element such that the laser beam jumps to a surface element in an adjacent line, then a further laser pulse is triggered, and it subsequently jumps back to the position of the current line. By jumping back and forth between two processing lines, the productivity of the processing can be increased further because two lines are processed in one passage over the wafer (the workpiece) and the number of passages is halved. This can also be advantageous if in this way work has to be performed at a slightly lower feed rate of the sample due to the increased number of laser pulses. By adapting the wafer layout, the advantage of this method will come to the fore even more by virtue of the structures (sensor elements) in adjacent lines being offset with respect to one another (for example, by half a structure length). Then, when jumping between the lines, the mirror must be offset substantially only in one axis and thus by a smaller amount. The offset should be kept as small as possible because otherwise imaging aberrations increase or larger, and thus more costly, lenses become necessary.

The use of the mask axes for the jump to the adjacent line requires a correspondingly larger laser beam (homogeneous surface area in the mask plane) and can thus reduce the full utilization of the laser energy because a larger region is blocked by the mask. The offset of the laser beam by the deflection mirror would avoid this disadvantage, but can result in slightly larger imaging aberrations, which means that one or the other variant can prove to be better suited, depending on the application.

The laser processing system has further possibilities for process optimization during the production of xMR magnetic field sensors. The operating system 195 connected to the control unit 190 comprises a pulse property setting device 197, with which pulse properties of the laser pulses can be variably set. For example, pulse duration, pulse height etc. can be modified within certain limits and thus be better adapted to the process.

One special feature consists in the fact that the pulse property setting device is configured in one mode to set the temporal pulse shape of the laser pulses. It is thus possible thereby to set the shape of the pulse in an intensity-time diagram, that is to say the temporal distribution of the laser intensity within a pulse. It is thereby possible to achieve a temperature profile that is adapted better to the process.

For illustration purposes, FIG. 7A shows an intensity-time diagram in which a standard pulse PS is shown on the left and a modified laser pulse PSM with a particularly advantageous temporal distribution of the laser energy is shown on the right. FIG. 7B shows, in a corresponding temperature-time diagram, the respectively associated temperature profiles within the sample. In the regular pulse (left), there is a risk that for a short period of time so much laser energy is input that, although the blocking temperature T_{B} is reliably exceeded, the damage threshold T_{Z} of the workpiece material is also exceeded, which can result in the sensor elements being damaged.

By contrast, in the modified laser pulse PSM shown on the right, the temporal pulse shape is set such that the maximum intensity is lower than in the regular pulse, but the length a and the height b of the pulse following the maximum can be modified such that the intensity remains at an approximately constant level for a prolonged period of time before it drops sharply. The temperature profile illustrated therebelow can thereby be adjusted such that the blocking temperature T_{B} is reliably exceeded without the layers being destroyed. This can be useful in particular if the absorption by the layers greatly increases as the temperature rises.

The laser processing system 100 in FIG. 2 is equipped with devices for the camera-based observation of the processes on the workpiece 150. The camera-based observation of the processed workpiece region takes place, for example, at green light by a camera 170 through a beam splitter 172 and the imaging lens 140. In other words: an observation beam path extends from the workpiece, or the workpiece-side object plane of the imaging lens, through the imaging lens to the camera 170. An illumination beam path with which illumination light is guided from an observation light source 175 via reflection at the beam splitter 172 onto the section to be observed preferably likewise passes through the imaging lens. With a camera-based observation through the lens (TTL), particularly precise controls for compact overall dimensions of the components necessary for the measurement are possible.

The camera 170 is connected to the control unit 190 for the transmission of signals. The control unit comprises an evaluation unit for evaluating images from the camera by image processing. This evaluation can be used, for example, as part of camera-based position regulation and pulse triggering.

If required, there are numerous possibilities for increasing the productivity of the method or the system, for shortening the processing times and for enabling more efficient processing in this way. A few possibilities will be explained below by way of example.

Usually, the movement of the workpiece produced via the movement system is significantly slower than the movement speed that a scanner for the movement of a laser beam can achieve. As already mentioned above, the scanner can move quickly perpendicular to the movement direction of the workpiece and possibly also in the direction thereof to enable corrections depending on the location of the sensor elements and possibly for compensating the axial movement. A laser pulse is triggered in each case at the positions of the adjacent sensor elements. As a result, a wider region can be processed in one passage and the laser is better utilized, since more laser pulses are triggered per unit time. The processing time is thereby significantly shortened or the productivity is increased. Depending on the chosen size of the scan field used, an f-θ lens or, in the case of a very small scan field, possibly also an imaging lens without f-θ correction can be used. FIG. 2 schematically illustrates an arrangement with a scanner. The scanner is symbolized by the two curved double-headed arrows by the pivotable deflection mirror 115. In this arrangement, in which the scanner is arranged between the mask and the workpiece, the image of the mask on the workpiece would move.

A larger processing region on the workpiece may possibly also require a larger air gap in the magnet system of the magnetization unit, since the laser radiation irradiates the sample through the air gap. A rectangular orifice having a narrow slit in the movement direction of the movement system and a greater width perpendicular thereto can be advantageous. When programming a magnet orientation that is rotated by 90°, the slit is also rotated by 90°. It is possible to change the axial movement to the y-direction, and the scanning movement then takes place perpendicular thereto parallel to the x-direction. If required, the mask must also be rotated. Instead of the right-angled rotation, intermediate values such as 30° or 45° are also possible. In this case, the movements would be coordinated via both axes. Alternatively, the wafer can be rotated, and the magnetic field and the axial direction can then remain unchanged. In doing so, the mask may have to be rotated or interchanged. FIG. 4 shows the directions of the axial movement AX and the scanner movement SC by way of the dashed arrows SC and AX. The rectangular shape of the slit between the poles (dashed lines) can be selected such that the slit is narrower in the axial direction AX than perpendicular thereto (in the scanner direction SC).

A further possibility for increasing the efficiency consists in parallelization of the processing to the effect that two, three or more regions having a lateral offset with respect to one another in the mask plane are irradiated simultaneously at a given time and, as a result, a plurality of sensor elements can be programmed in parallel (at the same time). Such an acceleration of the processing is possible, for example, by way of a beam shaping element, such as a diffractive optical element, producing a multispot by splitting an incident laser beam into two or more laser beams which are incident on the mask with a lateral offset and, in their respective incidence region, illuminate in each case one or more mask apertures, with the result that a plurality of sensor elements can be irradiated at the same time with one laser pulse. The number of the generable spots of the beam shaping element would correspond to the number of sensor elements that are to be modified at the same time. A prerequisite herefor is that the assigned laser radiation source has the pulse energy required for irradiation. The distance between the individual laser spots must correspond to the distance between the sensor elements. If the geometry of the sensor elements is changed, one beam shaping element may possibly need to be interchanged for another. The curly bracket MS in FIG. 3 in the example groups together four mask apertures disposed in series. A multispot beam shaping element arranged between the laser source and the mask plane can be configured, for example, such that these four mask apertures can be irradiated at the same time with a single laser pulse.

A further option consists in the use of a plurality of laser radiation sources, which are imaged onto the sample via the same optical unit and the same mask. The arrangement is struck such that different regions of the mask are used. The positions of the two laser beams can be flexibly settable so that different distances between the sensor elements can be easily realized, possibly with different masks. FIG. 3 schematically illustrates, by way of the dashed circles LS1, LS2, how parallel processing can be realized, wherein two laser light sources operated in parallel are used at the same time. For example, the two encircled mask apertures can thereby be illuminated at the same time and, as a result, two sensor elements can be programmed at the same time.

Another possibility consists in the generation of a line beam which is scanned over the mask so that a plurality of sensor elements can be irradiated with the line at the same time. For this purpose, it is usually advantageous to use a plurality of pulses or a plurality of adjacent lines for irradiating a sensor element. The length of the lines should be set such that the remaining laser fluence is sufficient for the programming of the irradiated region. The width of the lines can then be significantly smaller than the width of the sensor element.

Depending on the manner in which the primary laser radiation is conditioned, different laser radiation sources can be used. One option for efficient programming of xMR sensors consists, for example, in the use of an excimer laser. Excimer lasers generally have a comparatively low coherence and can consequently be homogenized well, with the result that the fluence can be set exactly uniformly on the entire irradiated surface. In addition, high laser powers are available, and large surface areas can be processed therefore with one pulse. It is thus possible to realize fast processing with a comparatively low laser pulse repetition rate.

1. A method for producing an xMR magnetic field sensor with at least one xMR sensor element from a workpiece having one or more layers of an xMR multilayer system, comprising at least one magnetically hard reference layer with a reference magnetization direction, the method comprising:
a programming operation in which a spatial orientation of the reference magnetization direction in a sensor region provided to form an xMR sensor element is set and/or modified by heating the reference layer in a laser processing operation in the sensor region in a locally delimited manner beyond a threshold temperature by laser radiation, the heated region of the reference layer is exposed to an external magnetic field with a specifiable field direction to set the reference magnetization direction, and the heated region is subsequently cooled again to below the threshold temperature,
wherein
the laser processing operation comprises a mask projection operation, in which
a mask with at least one mask aperture is arranged in a mask plane arranged at a distance from a processing plane of the laser processing operation;
a region of the mask containing the mask aperture is irradiated with one or more laser pulses; and
a region of the mask aperture that is fully illuminated with laser radiation is imaged into the processing plane with the aid of an imaging lens arranged between the mask plane and the processing plane.

2. The method according to claim 1, further comprising a homogenization of the laser radiation such that an intensity distribution of the laser radiation that passes through a mask aperture and is incident on a sensor region is substantially constant over an entire cross section, varies by no more than 20% , or no more than 10%, wherein the homogenization is produced in a region between a laser radiation source and the mask plane in a manner such that an intensity distribution of the laser radiation that is incident on the mask aperture is specifiable by the homogenization.

3. The method according to claim 1, wherein a temporal pulse shape of the laser pulses is variably set such that a maximum intensity within a laser pulse is reduced in comparison with a regular laser pulse and a decay gradient of the laser intensity after the maximum intensity is exceeded is lower than for a regular laser pulse.

4. The method according to claim 1, wherein the workpiece is heated, before and/or during the irradiation with the laser, to an operating temperature that is higher than the ambient temperature and lower than the threshold temperature, and the operating temperature is 30° C. to 250° C., or 50° C. to 100° C.

5. The method according to claim 1, wherein the workpiece is actively cooled, during and/or after the irradiation with the laser, to a temperature below the threshold temperature, by applying a cooling fluid in a locally delimited region.

6. The method according to claim 1, wherein the workpiece is moved, during the irradiation with the laser, in a movement direction at a constant speed such that pulse triggering is effected during the movement of the workpiece without stopping, and the speed is 50 mm/s to 500 mm/s, or 150 mm/s to 300 mm/s.

7. The method according to claim 6, further comprising a motion-blur compensation, wherein, during the duration of a laser pulse, a laser beam incidence region on the workpiece is guided along with the aid of at least one controllable component to compensate any smearing of the incidence region in the movement direction of the workpiece, and as controllable component a deflection mirror in the beam path, a movement axis of a mask holding device or a scanner is controlled.

8. The method according to claim 1, wherein a controllable deflection mirror or a scanner or a movement axis of the mask holding unit is controlled after the irradiation of a surface element such that the laser beam jumps to a surface element in an adjacent line with sensor regions and a further laser pulse is triggered and subsequently jumps back to the position of the current line with sensor regions.

9. The method according to claim 1, further comprising parallelization of the irradiation, wherein, in addition to a first laser beam for irradiating a first region of the mask, at least one second laser beam for simultaneously irradiating a second region of the mask arranged with an offset in the mask plane adjacent to the first region is produced, and a first and at least one second laser beam source are used to produce the first and the second laser beam and/or a laser beam is split into two or more laser beams by beam shaping.

10. A system that produces xMR magnetic field sensors, wherein an xMR magnetic field sensor has an xMR sensor element having an xMR multilayer system that has at least one magnetically hard reference magnetic layer with a specifiable reference magnetization direction, comprising:
a control unit;
a laser processing station having a laser processing unit, controllable by the control unit, for producing a laser beam that is directable at a laser irradiation region in a processing plane of the laser processing unit;
a workpiece holding apparatus that receives a workpiece to be processed at a defined location;
a workpiece movement system that moves the workpiece to be processed in a working region of the laser processing station as a reaction to movement signals from the control unit;
a settable magnetization device that produces a magnetic field with a variably specifiable field direction which at least partially penetrates the workpiece in the laser irradiation region when the magnetization device is in a working configuration;
a mask projection system having a mask holding unit that arranges a mask forming at least one mask aperture in a mask plane located at a distance upstream of the processing plane and having an imaging lens to image the mask plane into the processing plane of the laser processing unit.

11. The system according to claim 10, further comprising an optical homogenization system, arranged between the laser radiation source and the mask plane, for homogenizing an intensity distribution within the laser beam, wherein the homogenization system has at least one element from the following group: a diffractive optical element; a spatial light modulator; a beam shaping optical fibre.

12. The system according to claim 10, further comprising a pulse property setting device to variably set pulse properties of the laser pulses, wherein the pulse property setting device is configured in one mode to set a temporal pulse shape of the laser pulses.

13. The system according to claim 10, further comprising a heating device, controllable via the control unit, for actively heating a workpiece held by the workpiece holding apparatus to an operating temperature and/or by a cooling device, controllable via the control unit, for actively cooling a workpiece held by the workpiece holding apparatus.

14. The system according to claim 10, further comprising a movement system, controllable via a control unit in a manner such that the workpiece is moved, during the irradiation with a laser, in a movement direction at a constant speed such that pulse triggering is effected during the movement of the workpiece without stopping, wherein the speed is 50 mm/s to 500 mm/s, or 150 mm/s to 300 mm/s.

15. The system according to claim 14, further comprising a motion-blur compensation device with at least one controllable component which is controlled such that, during the duration of a laser pulse, a laser beam incidence region on the workpiece is guided along to compensate any smearing of the incidence region in the movement direction of the workpiece, wherein the motion-blur compensation device has a dynamically controllable laser beam deflection device arranged in a laser beam path between the laser source and the processing plane, and/or the motion-blur compensation device is configured to displace the mask during the duration of a laser pulse.

16. The system according to claim 10, wherein the control unit is configured in an operating mode such that a controllable deflection mirror or a scanner or a movement axis of the mask holding unit is controlled after the irradiation of a surface element such that the laser beam jumps to a surface element in an adjacent line with sensor regions and a further laser pulse is triggered and subsequently it jumps back to the position of the current line with sensor regions.

17. The system according to claim 10, wherein the laser processing unit is configured for parallelization of the irradiation of the mask, in which, in addition to a first laser beam for irradiating a first region of the mask, at least one second laser beam for irradiating a second region which is arranged with an offset in the mask plane adjacent to the first region is producible.

18. The system according to claim 10, wherein the laser processing unit comprises:
(i) a multispot beam shaping element configured to generate, from an individual incident laser beam upstream of the mask plane, a first laser beam and at least one second laser beam, the first and the second laser beam being directed at laterally offset regions of the mask, and illuminated mask apertures in the offset regions are imageable together into the processing plane by the imaging lens; and/or
(ii) a first laser radiation source that produces a first laser beam and at least one second laser radiation source that produces a second laser beam, the first and the second laser beam being directed at laterally offset regions of the mask, and illuminated mask apertures in the offset regions are imageable together into the processing plane by the imaging lens.

19. The system according to claim 10, wherein the magnetization device has two or more magnet units, which are held in a movably mounted magnet holder and are arrangeable selectively in a working position by displacing the magnet holder, and different magnet units have permanent magnets with different orientations of their magnetic axes and/or with different magnetic field strengths, and/or in that the magnetization device has a magnet holder that is mounted rotatably about an axis that is oriented perpendicularly to the processing plane or displaceably perpendicular to said axis.
